(19) United States
(12) Patent Application Publication
(10) Pub. No.: US 2008/0081464 A1
(43) Pub. Date: Apr. 3, 2008

(54) METHOD OF INTEGRATED SUBSTRATED PROCESSING USING A HOT FILAMENT HYDROGEN RADICAL SOUCE

(75) Inventors: Tsukasa Matsuda, Yamanashi (JP); Isamu Sakuragi, Yamanashi-Ken (JP)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/537,573

(22) Filed: Sep. 29, 2006

(51) Int. Cl. H01L 21/34

(52) U.S. Cl. 438/660; 257/E21.459

(57) ABSTRACT

A method of integrated processing is provided for a substrate in the substrate processing tool. The substrate contains an etch feature in a dielectric film and an exposed metal interconnect pattern formed underneath the etch feature. The integrated process includes pretreating exposed surfaces of the etch feature and the exposed metal interconnect pattern with a flow of hydrogen radicals generated by thermal decomposition of H₂ gas by a hot filament hydrogen radical source separated from the substrate by a showerhead plate containing gas passages facing the substrate. The integrated process further includes depositing a barrier metal film over the pretreated exposed surfaces, and forming a Cu metal film on the barrier metal film.

### CROSS REFERENCE TO RELATED APPLICATIONS

The present invention is related to U.S. patent application Ser. No. 11/537,562, entitled PROCESSING SYSTEM CONTAINING A HOT FILAMENT HYDROGEN RADICAL SOURCE FOR INTEGRATED SUBSTRATE PROCESSING, filed on even date herewith; U.S. patent application Ser. No. 11/277,908, entitled METHOD FOR INTEGRATING A CONFORMAL RUTHENIUM LAYER INTO COPPER METALLIZATION OF HIGH ASPECT RATIO FEATURES; and U.S. patent application Ser. No. 11/142,457, entitled SUBSTRATE PROCESSING METHOD AND FABRICATION OF A SEMICONDUCTOR DEVICE; and the entire contents of which are herein incorporated by reference.

### FIELD OF THE INVENTION

The present invention generally relates to a processing system and method for pretreating a substrate during integrated processing, and more particularly to a processing system containing a hot filament hydrogen radical source and a method for pretreating a substrate with hydrogen radicals.

### BACKGROUND OF THE INVENTION

Advanced semiconductor integrated circuit devices use a multilayer interconnect structure where a number of stacked interconnect layers are used for electrically connecting a large number of device elements formed on a substrate, where each interconnect layer covers an interconnect pattern in a dielectric film.

Damascene or dual damascene processing is used extensively with such a multilayer interconnect structure, where etched features are formed in a dielectric film in the form of an interconnect pattern containing trenches and vias (holes). The etched features are filled with a low-resistance metal such as a bulk Cu where a barrier metal film separates the dielectric film from the bulk Cu, and any excess Cu is removed from the surface of the dielectric film by a chemical mechanical polishing (CMP) process.

Highly miniaturized semiconductor devices that are characterized by increasingly larger integration density of multilayer interconnect structures exhibit increasing signal delays due to stray capacitance formed between adjacent interconnect patterns. Low dielectric constant (low-k) films may be used in combination with Cu layers for reducing the stray capacitance and for reducing the power consumption of the devices. The low-k dielectric films contain materials that can provide a dielectric constant of about 3, or lower, compared to a dielectric constant of 3.9 for the conventional SiO₂ dielectric material.

### SUMMARY OF THE INVENTION

According to one embodiment of the invention, a processing system is provided for pretreating a substrate with hydrogen radicals. The processing system contains a substrate holder configured for supporting and controlling the temperature of the substrate, a hot filament hydrogen radical source for generating hydrogen radicals, and a controller configured for controlling the hot filament hydrogen radical source. The hot filament hydrogen radical source includes a showerhead assembly containing an internal volume and a showerhead plate having gas passages facing the substrate for exposing the substrate to the hydrogen radicals, and at least one metal wire filament within the internal volume, where the at least one metal wire filament is heated to thermally dissociate H₂ gas into the hydrogen radicals.

According to another embodiment of the invention, a method of integrated substrate processing in a substrate processing tool is provided. The substrate contains an etch feature in a dielectric film and an exposed metal interconnect pattern formed underneath the etch feature. The integrated process includes pretreating exposed surfaces of the etch feature with a flow of hydrogen radicals generated by thermal decomposition of H₂ gas by a hot filament hydrogen radical source separated from the substrate by a showerhead plate containing gas passages facing the substrate, depositing a barrier metal film over the exposed surfaces of the pretreated etch feature, and forming a Cu metal film on the barrier metal film.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIGS. 1A-1C are schematic diagrams of a dual damascene process for forming a multilayer interconnection structure;

FIGS. 2A and 2B are schematic diagrams illustrating problems encountered during a process of forming a multilayer interconnection structure;

FIG. 3 are schematic diagrams illustrating additional problems encountered during a process of forming a multilayer interconnection structure;

FIG. 4 is a schematic diagram of a processing system for generating and exposing hydrogen radicals to a substrate according to an embodiment of the invention;

FIGS. 5A and 5B are schematic diagrams of metal wire filament assemblies for generating hydrogen radicals according to embodiments of the invention;

FIGS. 6A-6H are schematic diagrams of a method of integrated substrate processing according to an embodiment of the invention;

FIG. 7 is a schematic diagram of a plasma-enhanced atomic layer deposition (PEALD) system used for depositing a barrier metal film according to an embodiment of the invention;

FIG. 8 is a timing diagram of a deposition sequence for depositing a barrier metal film by the PEALD system of FIG. 7;

FIG. 9 is a schematic diagram of a CVD system used for depositing a Cu seed layer according to an embodiment of the invention;

FIG. 10 is a schematic diagram showing a multilayer interconnect structure according to an embodiment of the invention;

FIG. 11A is a schematic diagram of a substrate processing tool according to embodiments of the invention; and

FIG. 11B is a process flow diagram for integrated substrate processing using the substrate processing tool depicted in FIG. 11A according to embodiments of the invention.

### DETAILED DESCRIPTION OF SEVERAL EMBODIMENTS OF THE INVENTION

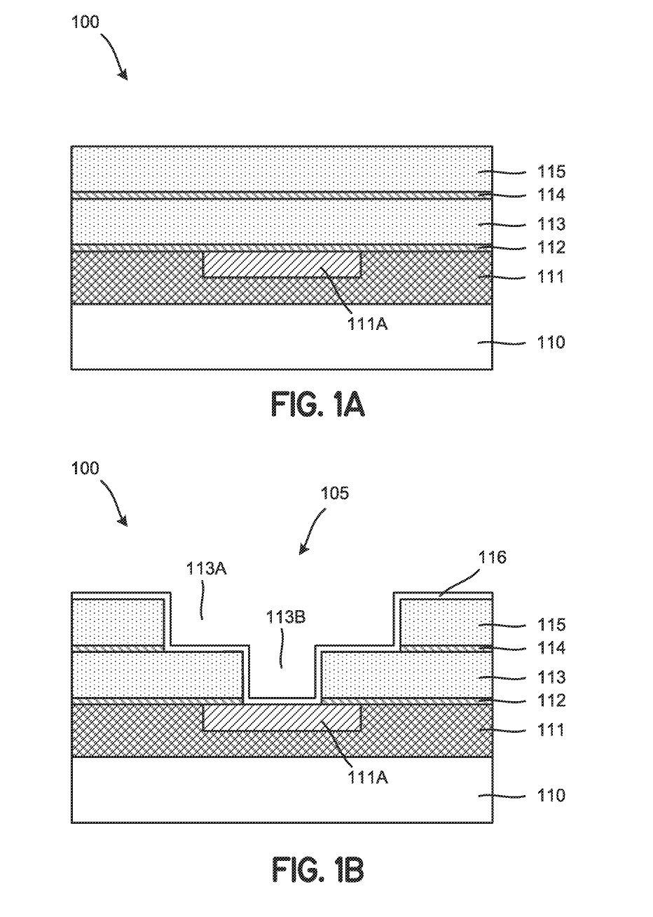

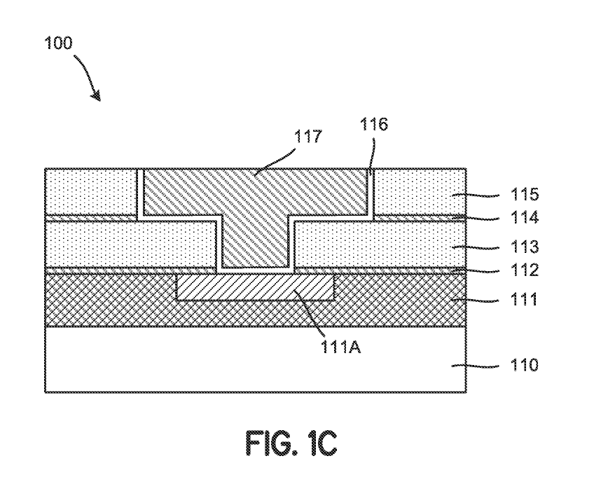

FIGS. 1A-1C are schematic diagrams of a dual damascene process for forming a multilayer interconnection structure. In FIG.1 A, the structure 100 contains an interconnect pattern 111A of a low-resistance metal such as Cu formed in a SiO₂ film 111 on a silicon substrate 110. Furthermore, an etch stop film 112 is formed on the interconnect pattern 111A and the SiO₂ film 111, and a low-k dielectric film 113 is formed on the etch stop film 112. Furthermore, an etch stop film 114 is formed on the low-k dielectric film 113, and a low-k dielectric film 115 is formed on the etch stop film 114. The etch stop films 112 and 114 can, for example, contain SiN. The low-k dielectric films 113 and 115 can, for example, contain SiCOH.

In FIG. 1B, an etch feature 105 containing a trench 113A and via (hole) 113B are formed in the dielectric films 113 and 115 by a dry etching process, such that the Cu interconnect pattern 111A is exposed at the bottom of the via 113B. As will be described in detail below, various problems are encountered following the dry etching process used for forming the trench 113A and via 113B. Embodiments of the invention provide solutions for reducing or eliminating those problems. FIG. 1B also shows a conformal barrier metal film 116 that covers the bottom and sidewall surfaces of the trench 113A and the via 113B.

The trench 113A and via 113B in FIG. 1B are subsequently filled with bulk Cu metal, and any excess Cu on the dielectric film 115 and the barrier metal film 116 on the top surface of the dielectric film 115 are removed by a CMP process. FIG. 1C shows a conductive Cu pattern 117 embedded in the dielectric films 113 and 115 following the CMP process. The conductive Cu pattern 117 can, for example, be a Cu interconnect pattern or a Cu conductive plug.

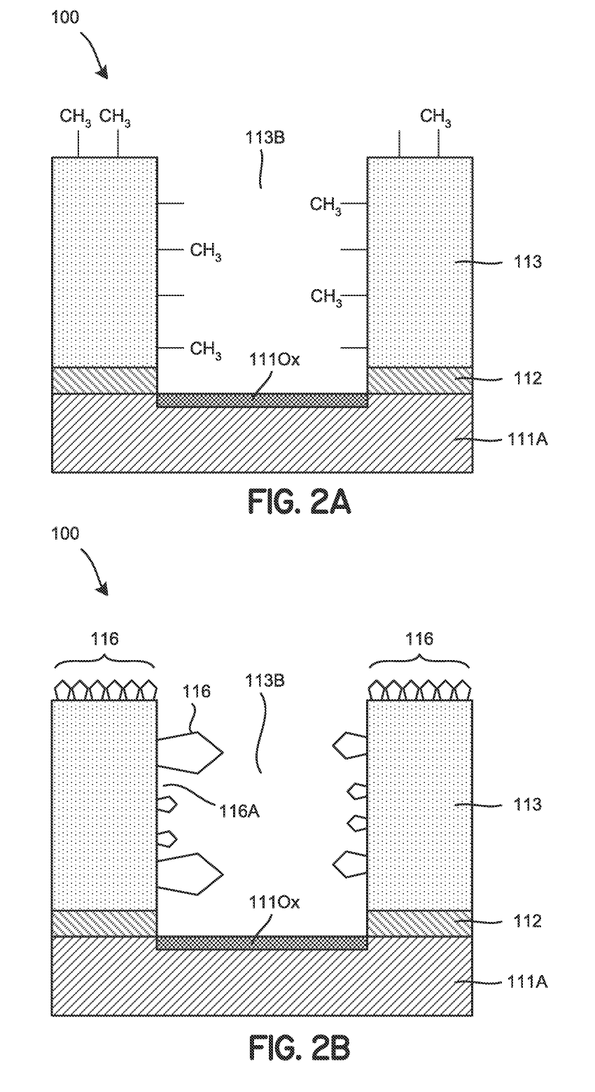

FIGS. 2A and 2B are schematic diagrams illustrating problems encountered during a process of forming a multilayer interconnection structure. In particular, FIGS. 2A and 2B depict problems encountered after a dry etching process used to form the via 113B and before depositing the barrier metal film 116 shown in FIG. 1B. Referring to FIG. 2A, when the via 113B is formed in the dielectric film 113 by the dry etching process, sidewall surfaces of the via 113B and other surfaces of the dielectric film 113 exposed to the dry etching process may become terminated by an etching residue containing methyl groups (CH₃) originating from the low-k dielectric film 113 and/or from the etching gas.

If a substrate containing the via 113B shown in FIG. 2A is exposed to an oxygen-containing environment, for example air, then water and organic materials from the air may adsorb on the exposed surfaces of the dielectric film 113, including the via 113B and the sidewall surfaces of the interconnect trench (not shown). Furthermore, the Cu interconnect pattern 111A at the bottom part of the via 113B may become oxidized by oxygen or water (e.g., by exposure to air or other oxidizing environments), thereby forming a high electrical resistance oxide layer 111Ox on the surface of the Cu interconnect pattern 111A as depicted in FIG. 2A. Although most of the adsorbed water and organic materials may be removed by a degassing process where the substrate is, for example, annealed in the presence of an inert gas, the oxide layer 111Ox cannot be removed by such a degassing process. Furthermore, complete removal of the methyl groups that terminate the surfaces of the dielectric film 113 is difficult.

When the barrier metal film 116 is formed on the structure of FIG. 2A by a sputtering process, a CVD process, a PEALD process, or an ALD process, nucleation of the barrier metal film 116 may occur at surface sites containing the methyl groups, resulting in formation of a discontinuous barrier metal film 116. For example, as depicted in FIG. 2B, the exposed surfaces of the dielectric film 113 may have a large number of defects 116A containing little or no barrier metal film 116.

When the via 113B in FIG. 2B is subsequently filled with Cu metal, the Cu metal atoms may come into contact with and diffuse into the dielectric film 113 due to the defects 116A in the barrier metal film 116. This Cu diffusion may have serious effects on the operation of the device due to critical problems such as increased dielectric constant of the low-k dielectric film 113 and increased leakage current in the device. Furthermore, the presence of the oxide layer 111Ox at the bottom of the via 113B may result in poor adhesion of the Cu metal to the underlying Cu interconnect pattern 111A and/or increase in the contact resistance between the Cu metal fill and the Cu interconnect pattern 111A.

Conventional substrate cleaning or treating methods that are performed after formation of the structure depicted in FIG. 2A, but before deposition of the barrier metal film 116, involve treating the surfaces of the dielectric film 113 with a plasma, for example an Ar plasma. The Ar plasma exposure includes treating sidewall surfaces of the via 113B and the exposed surface of the Cu interconnect pattern 111A at the bottom of the via 113B. The Ar plasma treatment is effective in removing impurities such as the methyl groups from the surfaces of the dielectric film 113, including the sidewall surfaces of the via 113B, and also in removing the oxide layer 111Ox exposed at the bottom of the via 113B by a sputter etching process.

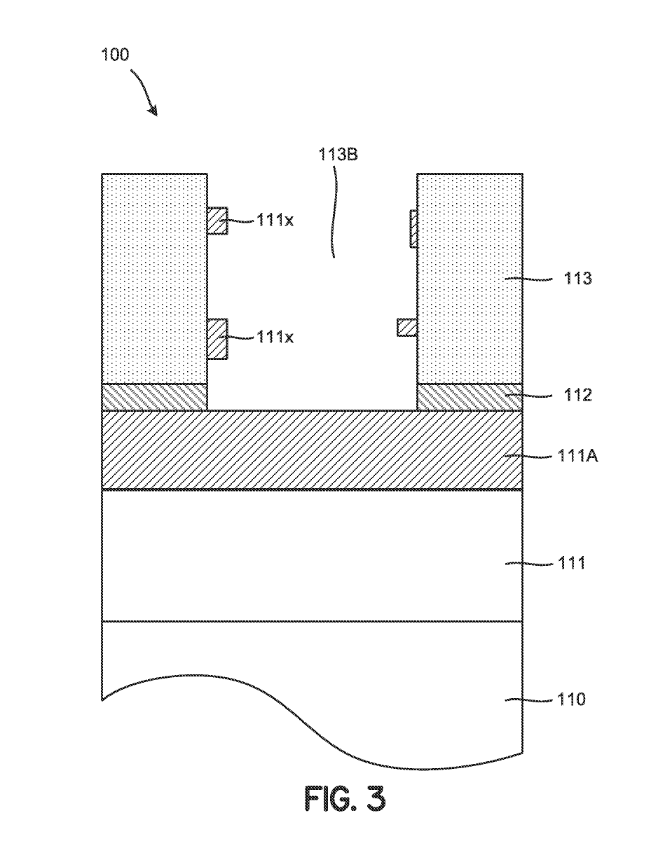

However, such an Ar plasma treatment has important drawbacks and limitations. In particular, while impurities adsorbed on the sidewall surfaces of the via 113B may be successfully removed by the Ar plasma treatment, sputter etching of the oxide layer 111Ox may cause re-deposition of the sputter-etched Cu oxide material 111x on the sidewall surfaces of the via 113B. This is schematically depicted in FIG. 3. The re-deposited Cu oxide material 111x is in direct contact with the sidewall surfaces of the via 113B, and it is therefore not possible to prevent diffusion of the Cu atoms in the re-deposited Cu oxide material 111x into the dielectric film 113 by subsequently depositing the barrier metal film 116 over the structure 100.

Furthermore, an Ar plasma treatment may modify the low-k dielectric film 113 by increasing the dielectric constant of the dielectric film 113 in the vicinity of the contact at the bottom of the via 113B. Any increase in the dielectric constant can directly affect operation of a high-speed semiconductor device. In one example, a (low-density) dielectric film 113 may contain methyl functional groups in the bulk of the film 113, in addition to the adsorbed methyl groups depicted in FIG. 2A. In addition to removing the adsorbed methyl groups, an Ar plasma treatment may also remove the methyl functional groups from the bulk of the dielectric film 113, thereby increasing the density of the dielectric film 113 and the dielectric constant.

Embodiments on the invention provide a method for reducing or eliminating the abovementioned problems in the fabrication of a semiconductor device. Following formation of an etch feature in a dielectric film by a dry etching process, embodiments of the invention provide a method that forms active surfaces in the etched feature by removing adsorbed impurities from the etched feature without damaging the dielectric film. Furthermore, the method reduces an oxidized metal film formed at the exposed portion of a interconnect pattern at the bottom of the feature to the corresponding metal without sputtering the exposed interconnect pattern.

According to one embodiment of the invention, a method of integrated substrate processing is provided. The method includes providing a substrate containing an etch feature in a dielectric film, where a metal interconnect pattern formed underneath the etch feature is exposed, and performing an integrated process on the substrate in a substrate processing tool. The integrated process includes pretreating surfaces of the etch feature with a flow of hydrogen radicals. The flow of hydrogen radicals is generated by thermal decomposition of H₂ gas by a hot filament source separated from the substrate by a showerhead plate containing gas passages facing the substrate. The integrated process further includes depositing a barrier metal film over the surfaces of the pretreated etch feature and the exposed metal interconnect pattern, and forming a metal film on the barrier metal film. The steps of depositing a barrier metal film, forming a metal film, and any steps between the depositing and the forming, are performed without exposing the substrate to an oxidizing environment such as air.

Embodiments of the invention are particularly useful when applied to processing of low density low-k dielectric films having a dielectric constant of 3.0 or lower. For example, the low density low-k dielectric films can include SiCOH films formed by CVD process, inorganic spin-on dielectric (SOD) films, and organic polymer films. The low density low-k dielectric films may be porous films.

According to one embodiment of the invention, a processing system is provided for integrated substrate processing in a substrate processing tool. The processing system contains a substrate holder configured for supporting and controlling the temperature of a substrate and a hot filament hydrogen radical source for generating hydrogen radicals. The hot filament hydrogen radical source includes a showerhead assembly containing an internal volume, at least one metal wire filament within the internal volume, where the at least one metal wire filament is heated to thermally dissociate H₂ gas into the hydrogen radicals, a showerhead plate having gas passages facing the substrate for exposing the substrate to the hydrogen radicals, and a controller configured for controlling the hot filament hydrogen radical source.

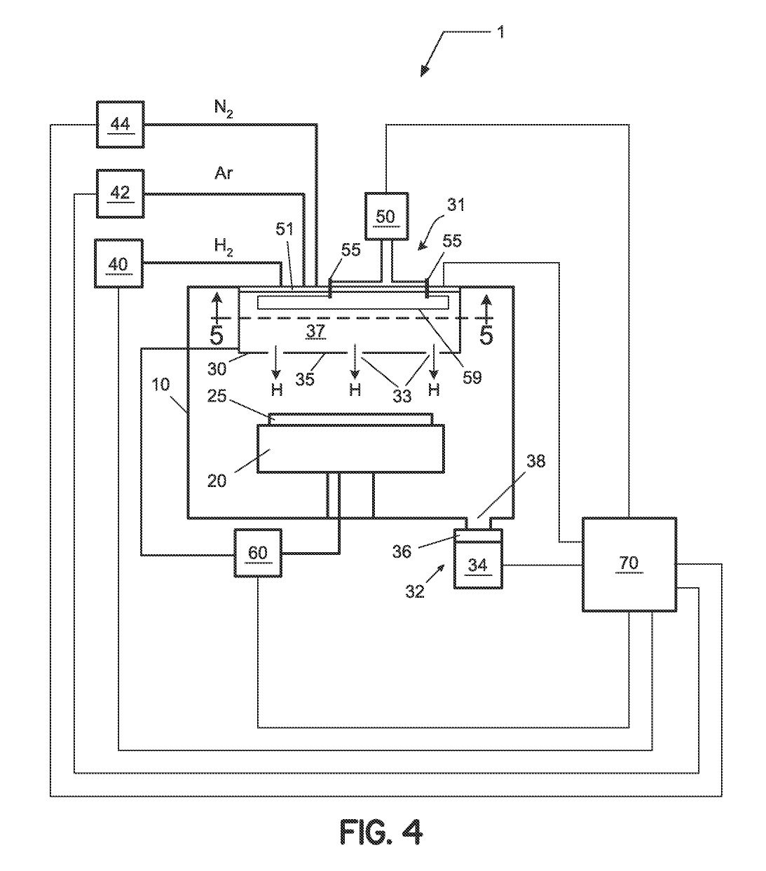

FIG. 4 is a schematic diagram of a processing system for generating and exposing hydrogen radicals to a substrate according to an embodiment of the invention. The processing system 1 contains a process chamber 10 having a substrate holder 20 configured to support a substrate 25 to be processed. The processing system 1 further contains a hot filament hydrogen radical source 31 for generating hydrogen radicals. The hot filament hydrogen radical source 31 contains a showerhead assembly 30 having an internal volume 37 and a showerhead plate 35 facing the substrate 25. The showerhead plate 35 contains a plurality of gas passages 33 for exposing the hydrogen radicals generated in the internal volume 37 to the substrate 25. In one example, the showerhead assembly 30 can contain between 10 and 100 gas passages 33, where each gas passage 33 may, for example, have a diameter between 3 mm and 10 mm. The showerhead assembly 30 is coupled to a first gas supply system 40, a second gas supply system 42, and a third gas supply system 44, to introduce H₂, Ar, and N₂ gases, respectively, to the internal volume 37 of the showerhead assembly 30. According to one embodiment of the invention, hydrogen radicals may be formed from a process gas consisting of H₂ gas. According to another embodiment of the invention, hydrogen radicals may be formed from a process gas containing H₂ gas and an inert gas, for example one or more of Ar and N₂.

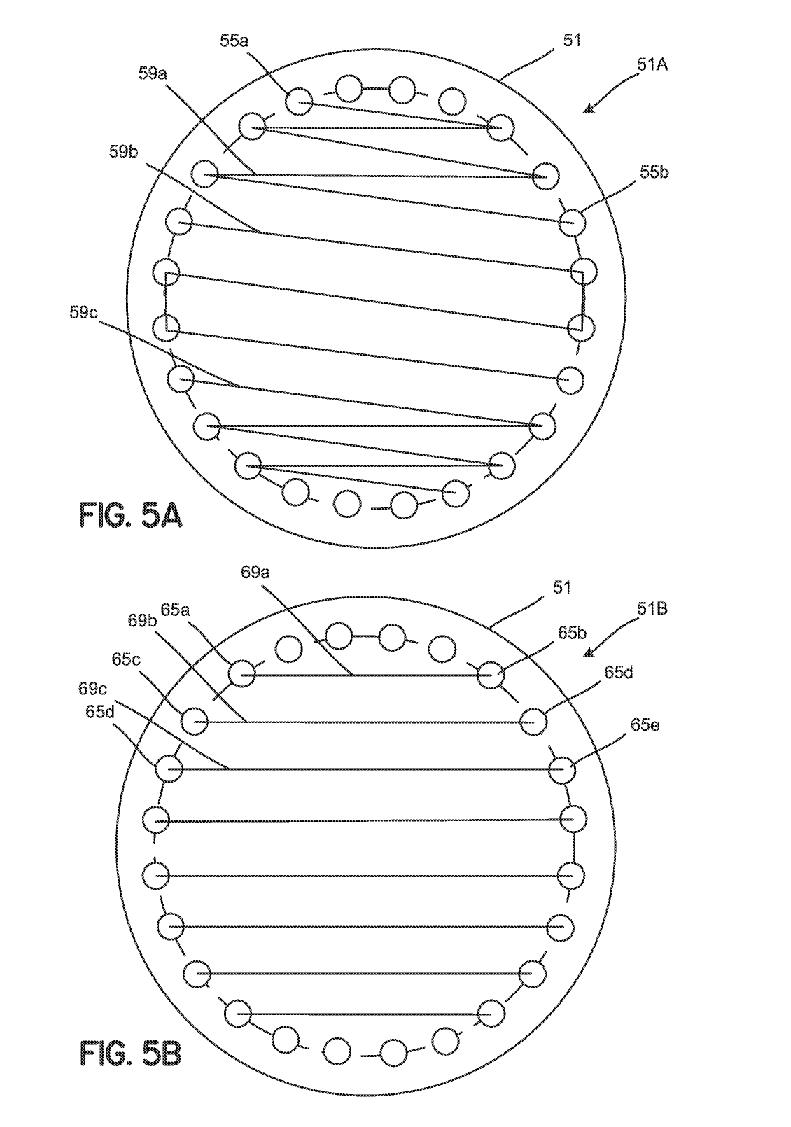

The internal volume 37 contains at least one metal wire filament 59 for generating the hydrogen radicals by thermal dissociation of H₂ in the internal volume 37. The at least one metal wire filament 59 may, for example, contain tungsten (W) metal or thoriated W metal. Thermal dissociation of H₂ in the internal volume 37 is carried out by heating the at least one metal wire filament 59 to a desired temperature using power source 50 and electrical connectors (power feedthroughs) 55 mounted on flange 51. The at least one metal wire filament 59 may be heated to a temperature between 1200° C. and 2500° C., or a temperature between 1400° C. and 1600° C. The power source 50 may be a DC power source or an AC power source. Exemplary metal wire filament assemblies are described below in reference to FIG. 5.

The hot filament hydrogen radical source 31 provides high flow of hydrogen radicals from the internal volume 37 through the gas passages 33 to the substrate 25. Unlike in conventional plasma sources, substantially no hydrogen ions are formed by the thermal dissociation of the H₂ gas by the at least one heated metal wire filament 59, and thus the substrate 25 is not exposed to any potentially damaging ions or electrons. Furthermore, the presence of the showerhead plate 35 effectively reduces or eliminates light radiation from the at least one metal wire filament 59 that may damage the substrate 25. In addition, the presence of the showerhead plate 35 effectively reduces radiative heating of the substrate 25 by the at least one heated metal wire filament 59. The temperature of the showerhead assembly 30 may be controlled by the temperature control system 60 during substrate processing to further reduce the heating of the substrate 25 by the at least one metal wire filament 59.

Still referring to FIG. 4, the processing system 1 includes a controller 70 that can be coupled to process chamber 10, substrate holder 20, showerhead assembly 30, power source 50, and temperature control system 60. In addition to controlling the temperature of the showerhead assembly 30, the temperature control system 60 is configured to control the temperature of the substrate 25 by controlling the temperature of the substrate holder 20 during substrate processing. Alternatively, or in addition, controller 70 can be coupled to one or more additional controllers/computers (not shown), and controller 70 can obtain setup and/or configuration information from an additional controller/computer.

In FIG. 4, singular processing elements (10, 20, 30, 40, 42, 44, 50, and 60) are shown, but this is not required for the invention. The processing system 1 can include any number of processing elements having any number of controllers associated with them in addition to independent processing elements.

The controller 70 can be used to configure any number of processing elements (10, 20, 30, 40, 42, 44, 50, and 60), and the controller 70 can collect, provide, process, store, and display data from processing elements. The controller 70 can comprise a number of applications for controlling one or more of the processing elements. For example, controller 70 can include a graphic user interface (GUI) component (not shown) that can provide easy to use interfaces that enable a user to monitor and/or control one or more processing elements.

Still referring to FIG. 4, the processing system 1 may be configured to process 200 mm substrates, 300 mm substrates, or larger-sized substrates. In fact, it is contemplated that the processing system 1 may be configured to process substrates, wafers, or LCDs regardless of their size, as would be appreciated by those skilled in the art. Therefore, while aspects of the invention will be described in connection with the processing of a semiconductor substrate, the invention is not limited solely thereto.

Still referring to FIG. 4, the substrate temperature can, for example, be maintained between room temperature and 500° C., or between 150° C. and 250° C., by the temperature control system 60 and the substrate holder 20. The temperature control system 60 contains temperature control elements, such as a cooling system including a re-circulating coolant flow that receives heat from substrate holder 20 and showerhead assembly 30 and transfers heat to a heat exchanger system (not shown), or when heating, transfers heat from the heat exchanger system. Additionally, the temperature control elements can include heating/cooling elements, such as resistive heating elements, or thermoelectric heaters/coolers, which can be included in the substrate holder 20, as well as the chamber wall of the process chamber 10 and any other component within the processing system 1.

In order to improve the thermal transfer between substrate 25 and substrate holder 20, substrate holder 20 can include a mechanical clamping system, or an electrical clamping system, such as an electrostatic clamping system, to affix substrate 25 to an upper surface of substrate holder 20. Furthermore, substrate holder 20 can further include a substrate backside gas delivery system configured to introduce gas to the back-side of substrate 25 in order to improve the gas-gap thermal conductance between substrate 25 and substrate holder 20. Such a system can be utilized when temperature control of the substrate is required at elevated or reduced temperatures. For example, the substrate backside gas system can comprise a two-zone gas distribution system, wherein the helium gas gap pressure can be independently varied between the center and the edge of substrate 25.

Furthermore, the process chamber 10 is coupled to a pressure control system 32, including a vacuum pumping system 34 and a valve 36, through a duct 38, wherein the pressure control system 32 is configured to controllably evacuate the process chamber 10 to a pressure suitable for performing a pretreating (cleaning) process on substrate 25. In one example, the pressure in the process chamber 10 and in the showerhead assembly 30 may be controlled between 10 mTorr and 10 Torr. In another example, the pressure may be maintained between 10 mTorr and 500 mTorr. The vacuum pumping system 34 can include a turbo-molecular vacuum pump (TMP) or a cryogenic pump, and valve 36 can include a gate valve for throttling the chamber pressure. In conventional plasma processing devices utilized for dry plasma etch, a TMP is generally employed. Moreover, a device for monitoring chamber pressure (not shown) can be coupled to the process chamber 10. The pressure measuring device can, for example, be a capacitance manometer.

Still referring to FIG. 1, the controller 70 can include a microprocessor, memory, and a digital I/O port capable of generating control voltages sufficient to communicate and activate inputs to the processing system 1 as well as monitor outputs from the processing system 1. Moreover, the controller 70 may be coupled to and may exchange information with the process chamber 10, substrate holder 20, showerhead assembly 30, first gas supply system 40, second gas supply system 42, third gas supply system 44, power source 50, temperature control system 60, and pressure control system 32. For example, a program stored in the memory may be utilized to activate the inputs to the aforementioned components of the processing system 1 according to a process recipe in order to perform a pretreating process where the substrate 25 is exposed to hydrogen radicals from the hot filament hydrogen radical source 31. One example of the controller 70 is a DELL PRECISION WORKSTATION 610™, available from Dell Corporation, Austin, Tex.

However, the controller 70 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, software is included for controlling the controller 70, for driving a device or devices for implementing the invention, and/or for enabling the controller 70 to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the processing system 1, or it may be remotely located relative to the processing system 1. For example, the controller 70 may exchange data with the processing system 1 using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the processing system 1 via a wireless connection.

FIG. 5A is a schematic diagram of a metal wire filament assembly for generating hydrogen radicals according to an embodiment of the invention. The exemplary metal wire filament assembly 51A contains three metal wire filaments 59a, 59b, 59c, and a plurality of electrical connectors 55a, 55b, etc, arranged in a circular pattern on the flange 51 for mounting and powering the metal wire filaments 59a, 59b, 59c. In FIG. 5A, the metal wire filament 59a is powered by the electrical conductors 55a and 55b. A plurality of other connectors are used to string the metal wire filament 59a in a “zig-zag” pattern between electrical connectors 55a and 55b. The metal wire filaments 59b and 59c are mounted and powered similar to the metal wire filament 59a.

FIG. 5B is a schematic diagram of a metal wire filament assembly for generating hydrogen radicals according to another embodiment of the invention. The metal wire filament assembly 51B is similar to the assembly 51A depicted in FIG. 5A but contains eight metal wire filaments 69a, 69b, 69c, etc., connected in a parallel manner to electrical connectors 65a, 65b, 65c, 65d, 65e, etc., mounted in a circular pattern on the flange 51.

As those skilled in the art will readily appreciate, many different combinations and configurations of metal wire filaments and electrical connectors may be used without departing from the scope of the invention. In one example, the electrical connectors and metal wire filaments may be arrange in a star-like pattern on the flange 51. In another example, the electrical connectors may be mounted as concentric circles on the flange 51.

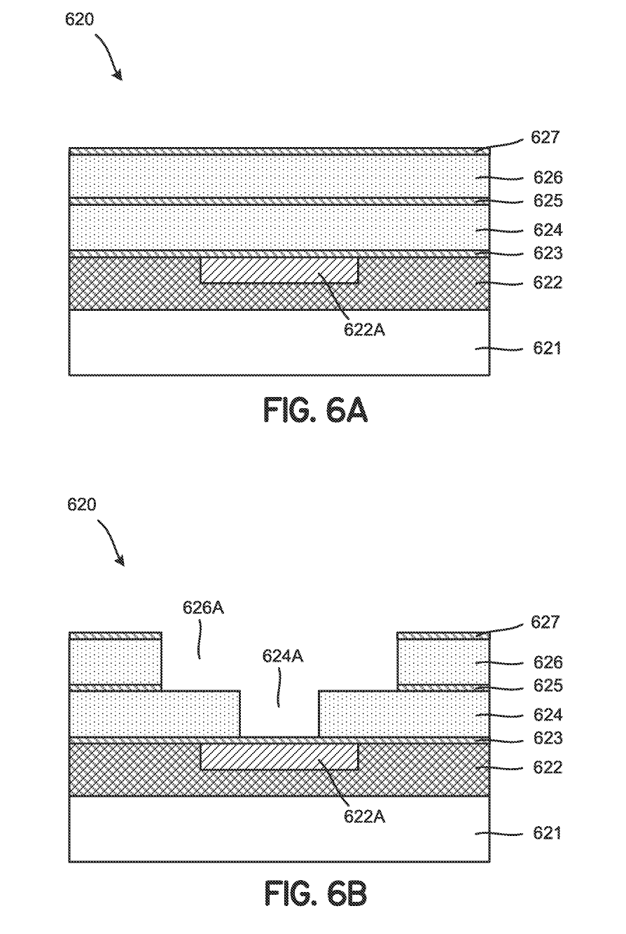

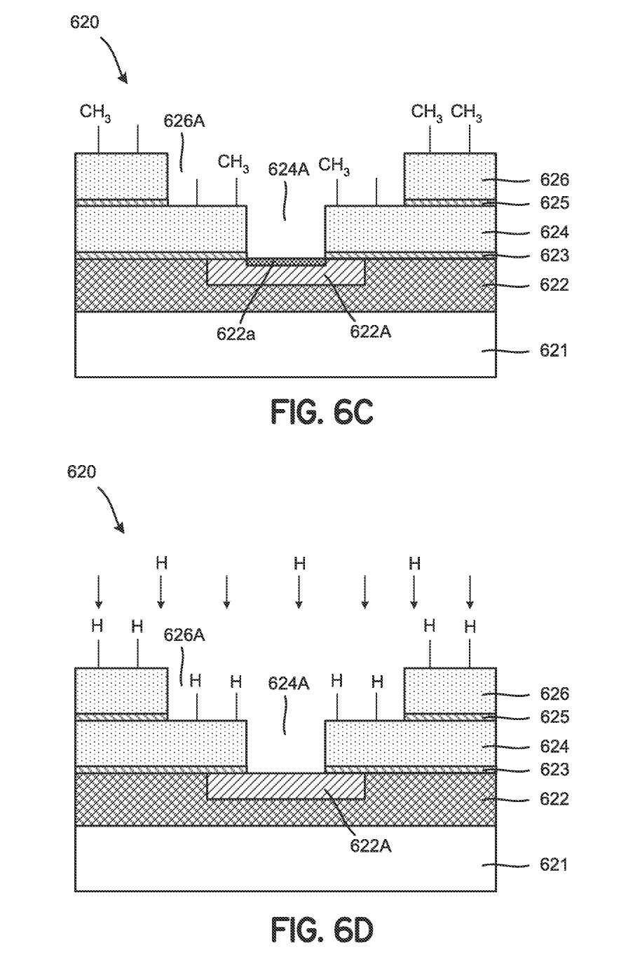

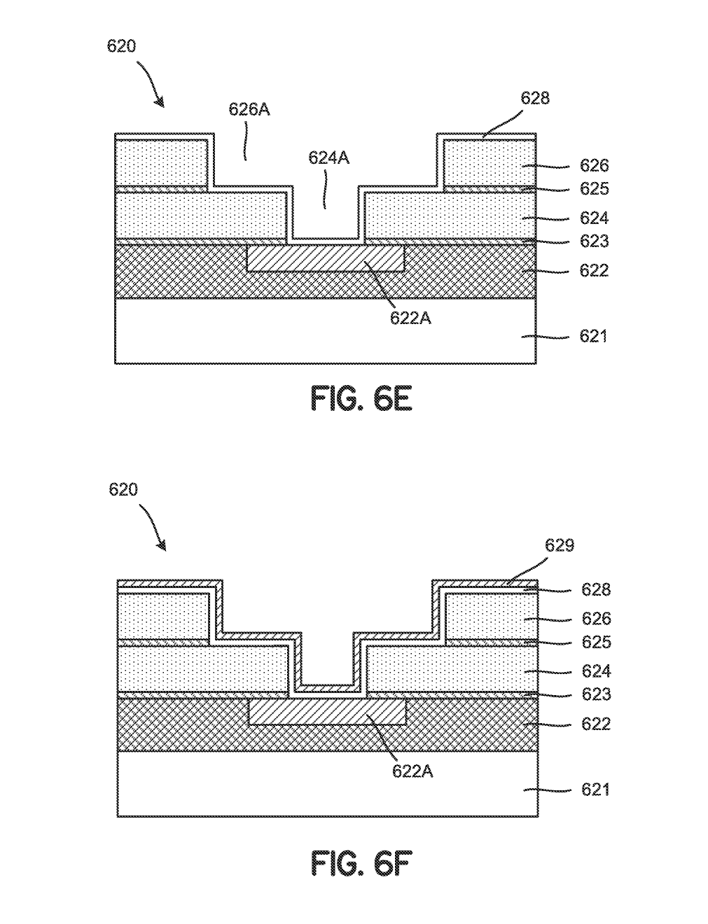

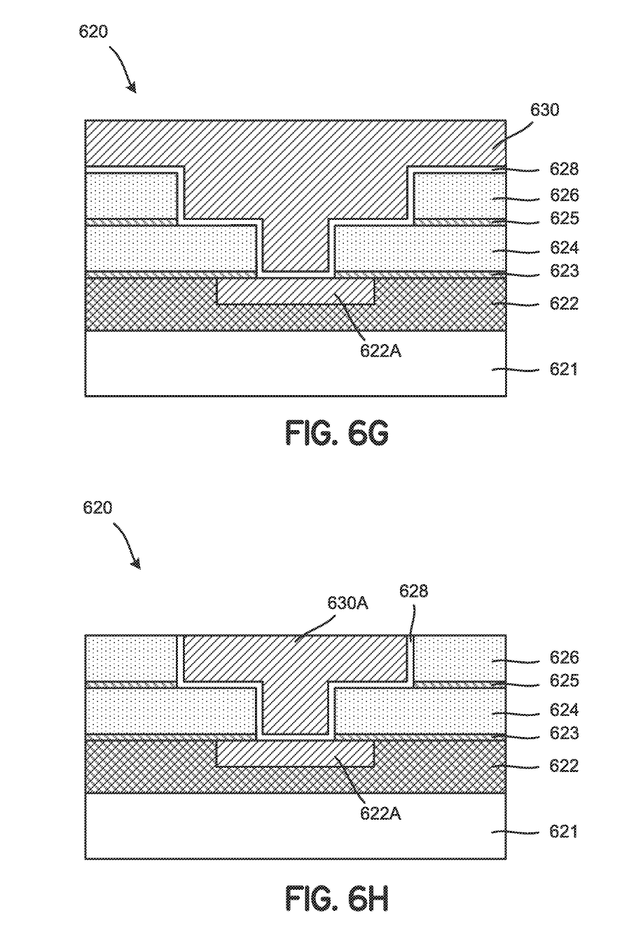

FIGS. 6A-6H are schematic diagrams of a method of integrated substrate processing according to an embodiment of the invention. In FIG. 6A, structure 620 is similar to the structure 100 depicted in FIG. 1A. The structure 620 contains a SiO₂ film 622 formed on a silicon substrate 621, and a Cu interconnect pattern 622A formed in the SiO₂ film 622 by a damascene process, where the Cu interconnect pattern 622A is exposed at the surface of the SiO₂ film 622. For example, the SiO₂ film can have a thickness of 200 nm, the Cu interconnect pattern 622A can have a width of 100 nm and a thickness of 100 nm. An etch stop film 623 is formed on the structure 100 of FIG. 6A, and a dielectric film 624 is formed on the etch stop film 623. The etch stop film 623 can also act as a barrier film. A second etch stop film 625 and a second dielectric film 626 are sequentially formed on the dielectric film 624, and a third etch stop film 627 is formed on the dielectric film 626. One or more of the etch stop films 623, 625, and 627 may contain SiN, and one or both of the dielectric films 624 and 626 may contain SiCOH. Furthermore, one or more of the films 623, 624, 625, 626, and 627 may be formed by a plasma-enhanced CVD process.

In one example, SiCOH films 624 and 626 may be formed using a parallel-plate radio frequency (RF) plasma CVD system. The processing conditions may include a process pressure of about 3 Torr and a substrate temperature of about 25° C. RF energy of 1000 watts (W) with a frequency of 13.50 MHz may be utilized. SiCOH films formed in this manner can have a dielectric constant of about 3.0. These processing conditions and dielectric constant are only exemplary, as SiCOH films with higher porosity and lower dielectric constants may be formed.

In general, low-k dielectric films used for the dielectric films 624 or 626 are classified as inorganic dielectric films and organic dielectric films. Inorganic films include spin-on-dielectric (SOD) films, for example alkyl siloxane polymers and hydrogen silsesquioxane (HSQ) films. Other low-k inorganic films include, for example, fluorine-doped silicon oxide films that may be deposited by CVD processing. These inorganic films may have a porous structure that is effective in lowering the dielectric constant further.

Organic dielectric films include organic polymer films such as PTFE films, polyimide films, fluorine-doped polyimide films, benzocyclobutene (BCB) films, parylene-N films, parylene-F films, alkyl silsesquioxane polymer films such as MSQ films, and hydro-organic silsesquioxane (HOSP) films. Other organic dielectric films include fluorine-doped carbon film, diamond-like carbon (DLC) films, and SiCOH films. As for inorganic dielectric films, organic dielectric films may have a porous structure that is effective in lowering the dielectric constant further.

FIG. 6B shows the structure 620 following a photolithographic patterning process. In particular, the etch stop film 627 in FIG. 6A is patterned by a photolithographic patterning process to produce a desired interconnect pattern, and the interlayer dielectric film 626 is patterned by a dry etching process using the etch stop film 627 as a hard mask. The dry etching process is performed until the etch stop film 625 is exposed. The dry etching process forms a trench 626A in the dielectric film 626. Next, a portion of etch stop film 625 in the trench 626A is patterned to form an opening corresponding to a desired via (hole) contact pattern, and the dielectric film 624 is subjected to a dry etching process that uses the etch stop films 625 and 627 as hard masks until the etch stop film 623 is exposed, and a via 624A is formed for the via-contact in the dielectric film 624. Alternately, the processing steps for forming the trench 626A and the via 624A may be reversed, i.e., the via 624A may be formed before the trench 626A.

Next, the etch stop film 623 at the bottom of the via 624A is removed by an etchback process to expose the Cu interconnect pattern 622A at the bottom of the via 624A. Furthermore, the etch stop film 627 on the dielectric film 626 and the etch stop film 625 at the bottom of the trench 626A are removed. The resulting structure 620 is shown in FIG. 6C.

The above-described process of forming the structure 620 shown in FIG. 6C results in adsorption of methyl groups onto the sidewall and bottom surfaces of the trench 626A and the via 624A, which can seriously degrade the quality of a barrier metal film to be deposited directly onto the structure 620. Furthermore, if the structure 620 is exposed to air, then water or organic materials in the air can adsorb onto the surfaces of the dielectric films 626 and 624, and the portion of the Cu interconnect pattern 622A exposed in the via 624A may become oxidized, thereby forming a Cu-oxide film 622a.

According to an embodiment of the invention, the structure 620 depicted in FIG. 6C is subjected to a degassing process for at least partially removing any adsorbed water and/or organic material and, subsequently, transferring the structure 620 into the processing system of FIG. 4 for a pretreating process. The pretreating process forms the structure 620 shown in FIG. 6D, where impurities are removed from the surfaces of the dielectric films 624 and 626, and the exposed surfaces become hydrogen terminated. In addition, hydrogen radicals in the pretreating process reduce the Cu-oxide film 622a to form a clean Cu metal surface of the Cu interconnect pattern 622A at the bottom of the via 624A.

Next, a barrier metal film 628 is deposited over the structure 620 as shown in FIG. 6E. According to one embodiment of the invention, the barrier metal film can contain a Ta-containing film. The Ta-containing film can contain TaN or TaCN. According to one embodiment of the invention, the Ta-containing film can contain TaN or TaCN and a Ta film deposited onto the TaN or TaCN film. According to another embodiment of the invention, the barrier metal film 628 can contain a Ru film deposited onto the Ta-containing film. According to yet another embodiment of the invention, the barrier metal film 628 can contain a Ti-containing film, for example Ti or TiZr. According to still another embodiment of the invention, the barrier metal film can contain a tungsten-containing film, for example W, WN, or WCN.

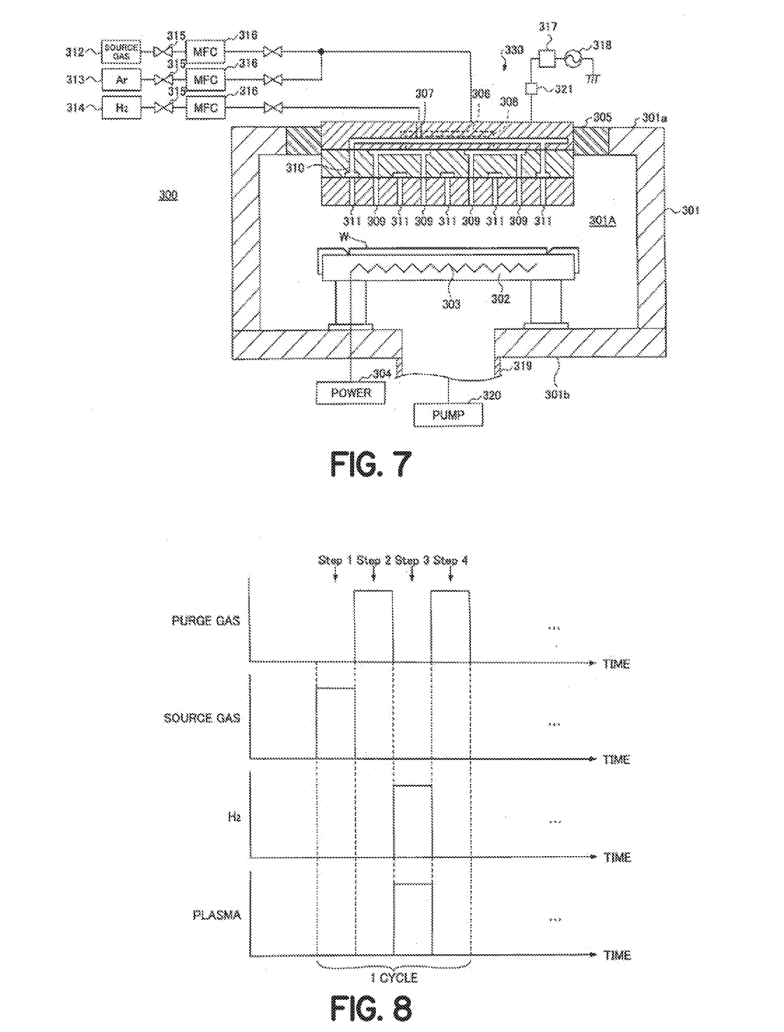

According to one embodiment of the invention, the substrate is introduced to a PEALD system 300 shown in FIG. 7, and the barrier metal film 628 is deposited over the structure 620. The barrier metal film 628 shown in FIG. 6E can contain a Ta-containing film, for example multiple alternating films of a conductive nitride or carbonitride material (e.g., TaN or TaCN) and a refractory metal (e.g., Ta). The barrier metal film 628 can be deposited by a PEALD process using a source gas and a reducing gas that are alternately exposed to the structure 620 of FIG. 6D with purge/evacuation steps between the alternating exposures.

FIG. 7 is a schematic diagram of a PEALD system used for depositing a barrier metal film according to an embodiment of the invention. The PEALD system 300 contains a process chamber 301 defining a processing space 301A that is evacuated by a pump 320 using an exhaust line 319, and a substrate holder 302 for supporting and heating a substrate W to be processed in the processing space 301A. The substrate holder 302 contains a heater 303, and the substrate W is heated to a predetermined temperature using the heater 303 and a power source 304. A showerhead 330 that faces the substrate W on the substrate holder 302 is provided in the upper part 301a of the process chamber 301. The showerhead 330 is electrically isolated from the rest of the process chamber 301 using an insulating member 305.

A gas inlet 306 is provided at the top of the showerhead 330 for introducing a source gas and a gas inlet 307 is provided for introducing a reducing gas such as H₂, where the gas inlet 306 is connected to a plurality of source gas passages 308 formed in the interior of the showerhead 330, and each source gas passage 308 is connected to a corresponding gas outlet hole 309 in a source gas dispersion chamber (not shown) within the showerhead 330.

The gas inlet 307 is connected to a plurality of reducing gas passages 310 in the showerhead 330, where each of the reducing gas passages 310 is connected to a corresponding reducing gas outlet hole 311 in a reducing gas dispersion chamber (not shown) within the showerhead 330.

In the post-mix showerhead 330, no mixing of source gas and reducing gas occurs inside the showerhead 330, and therefore, no premature film formation due to reduction of the source gas occurs inside the showerhead 330.

A gas source 312 containing the source gas and a gas source 313 containing an inert carrier gas such as Ar are connected to the gas inlet 306 using valves 315 and mass flow controllers 316, where the source gas from the gas source 312 is transported to the processing space 301A inside the process chamber 301 by the carrier gas from the gas source 313 via the shower head 330. A gas source 314 that provides a reducing gas is connected to the gas inlet 307 via valve 315 and mass flow controller 316, and H₂ gas is supplied from the gas source 314 to the process chamber 301. Although not shown, the PEALD system 300 may contain further gas lines for supplying another inert gas, for example Ar gas or N₂ gas, into the process chamber 301 for purging the processing space 301A.

A RF power source 318 is connected to the showerhead 330 via an impedance matcher 317 and a frequency matcher 321. Gas supplied to the process chamber 301 is plasma excited by applying RF power from the RF power source 318 to the showerhead 330 via the matcher 321 to facilitate a film forming reaction in the process chamber 301.

FIG. 8 is a timing diagram of a deposition sequence for depositing a barrier metal film by the PEALD system of FIG. 7. In Step 1, a source gas from the gas source 312 is introduced into the processing space 301A inside the process chamber 301 using an Ar carrier gas from the Ar gas source 313. When introduced into the process chamber 301, the gas molecules in the source gas chemically absorb onto the surface of the substrate W to be processed, and a layer of source molecules is formed on the surface of the substrate W. The thickness of the layer can be between less than one to several molecular layers.

Next, in Step 2, any remaining source gas in the processing space 301A is purged by introducing an Ar purge gas and/or by way of vacuum evacuation. In Step 3, H₂ gas from the gas source 314 is introduced into the processing space 301A.

Furthermore, in step 3, plasma is generated using the RF power source 318 to excite the H₂ gas and form hydrogen radicals or hydrogen ions in the processing space 301A. The hydrogen radicals and the hydrogen ions interact with the source gas molecules adsorbed onto the surface of the substrate W to form a film with a thickness between less than one to several molecular layers.

In Step 4, any remaining H₂ gas in the processing space 301A is purged by introducing an Ar purge gas and/or by way of vacuum evacuation.

According to one embodiment of the invention, the PEALD process depicted in FIG. 8 may be used to form a barrier metal film 628 containing a bilayer of a TaN or TaCN film and a Ta film. The TaN, TaCN, and Ta films may be deposited in either order. Furthermore, the barrier metal film 628 may contain multiple bilayers of TaN or TaCN films and a Ta film.

Processing conditions for the PEALD process may further include a processing pressure of 10⁻⁴ Torr-1 Torr in the processing space 301A, and the temperature of the substrate W may be maintained between about 150° C. and about 350° C., for example at about 250° C.

In Step 1 of FIG. 8, Ta(NC(CH₃)₂C₂H₅)(N(CH₃)₂)₃ (TAIMATA) precursor may be used for depositing a TaN or TaCN film on the substrate W. The precursor may be supplied at a rate of 10-100 mg/minute from the source 312 to a vaporizer (not shown), and the vaporized gas flowed to the process chamber 301 using an Ar carrier gas with a flow rate of 100-1000 sccm. Using an exposure time of about 1 second in Step 1, a molecular layer of the source molecules may be formed on the surface of the substrate W.

Next, in the Step 2, the processing space 301A is purged by supplying Ar and H₂ gas for about 1 second with flow rates of 100-2000 sccm and 0-2000 sccm, respectively.

In Step 3, H₂ gas from the gas source 314 is supplied with a flow rate of 200-2000 sccm. Furthermore, in Step 3, the RF power source 318 may provide a RF power of 100-2000 W with a frequency of 13.56 MHz to the showerhead 330 to form a plasma in the processing space 301A. Upon plasma exposure, the adsorbed TAIMATA molecules form a TaN or TaCN film on the structure 620 of FIG. 6D. The TaN or TaCN film can be several molecular layers thick and provide continuous coverage of the sidewall and bottom surfaces of the trench 626A and the via 624A.

Furthermore, in Step 4 of FIG. 8, the processing space 301A is purged by supplying Ar and H₂ gas for about 1 second with flow rates of 100-2000 sccm and 0-2000 sccm, respectively. Alternately, either Ar or H₂ gas may be used as a purge gas.

Steps 1-4 may be repeated to form a TaN or TaCN film with a desired thickness. The TaN or TaCN film thickness can, for example, be between about 1 nm and 5 nm, or between 1 nm and 3 nm. Other source gases that may be used for forming a TaN or TaCN film include metal organic compounds such as (pentakis(diethylamido) tantalum (Ta[N(C₂H₅)₂]₅, PDEAT), pentakis(ethylmethylamido) tantalum (Ta[N(C₂H₅CH₃)]₅, PEMAT), pentakis(methylamido) tantalum (Ta[N(CH₃)₂]₅, PDMAT), (t-butylimino tris(diethylamino) tantalum (Ta(NC(CH₃)₃)(N(C₂H₅)₂)₃, TBTDET), Ta(NC₂H₅)(N(C₂H₅)₂)₃, Ta(NC(CH₃)₃)(N(CH₃)₂)₃, tert-butyl-tris-ethylmethylamido tantalum Ta(NC(CH₃)₃)(NC₂H₅(CH₃)₃)₃, TBTEMAT), Ta(NC(CH₃)₂)₃, or Ta(NC₂H₅)₂)₃,

A Ta film may be formed by a PEALD process using TaCl₅ source gas, a processing pressure of 10⁻³ Torr −1 Torr in the processing space 301A, and a substrate temperature 150° C.-350° C. Furthermore, in the Step 1 of FIG. 8, TaCl₅ is supplied to the process chamber 301 from the gas source 312 with the flow rate of 1-10 sccm together with an Ar carrier gas having a flow rate of 100-1000 sccm. An exposure time of about 5 seconds may be used in Step 1 to form a molecular layer of the TaCl₅ the surface of the substrate W.

Next, in the Step 2, the processing space 301A is purged by supplying Ar and H₂ gas for about 1 second with flow rates of 100-2000 sccm and 0-2000 sccm, respectively.

In Step 3, H₂ gas from the gas source 314 is supplied with a flow rate of 200-2000 sccm. Furthermore, in Step 3, the RF power source 318 may provide a RF power of 100-2000 W with a frequency of 13.56 MHz to the showerhead 330 to form a plasma in the processing space 301A. Upon plasma exposure, the adsorbed TaCl₅ molecules form a Ta film on the structure 620 of FIG. 6E. The Ta film can be several molecular layers thick and provide continuous coverage of the sidewall and bottom surfaces of the trench 626A and the via 624A.

Furthermore, in Step 4 of FIG. 8, the processing space 301A is purged by supplying Ar and H₂ gas for about 1 second with flow rates of 100-2000 sccm and 0-2000 sccm, respectively. Alternately, either Ar or H₂ gas may be used as a purge gas.

Steps 1-4 may be repeated to form a Ta film with a desired thickness. The Ta film thickness can, for example, be between about 1 nm and 5 nm, or between 1 nm and 3 nm. Other source gases that may be used for forming a Ta film include TaF₅, TaBr₅, or TaI₅. According to another embodiment of the invention, the Ta film may be deposited by a PVD process such as sputtering process. According to one embodiment of the invention, the barrier metal film 628 may be exposed to Ar plasma sputtering to substantially completely remove the barrier metal film from the bottom of the via 624A and at least partially from the bottom of the trench 626A to reduce the contact resistance at the bottom of the via 624A.

After depositing the barrier metal film 628 (e.g., a TaN or TaCN/Ta bilayer film) depicted in FIG. 6F, a Cu seed layer 629 may be deposited on the barrier metal film 628 of the structure 620. This is depicted in FIG. 6F.

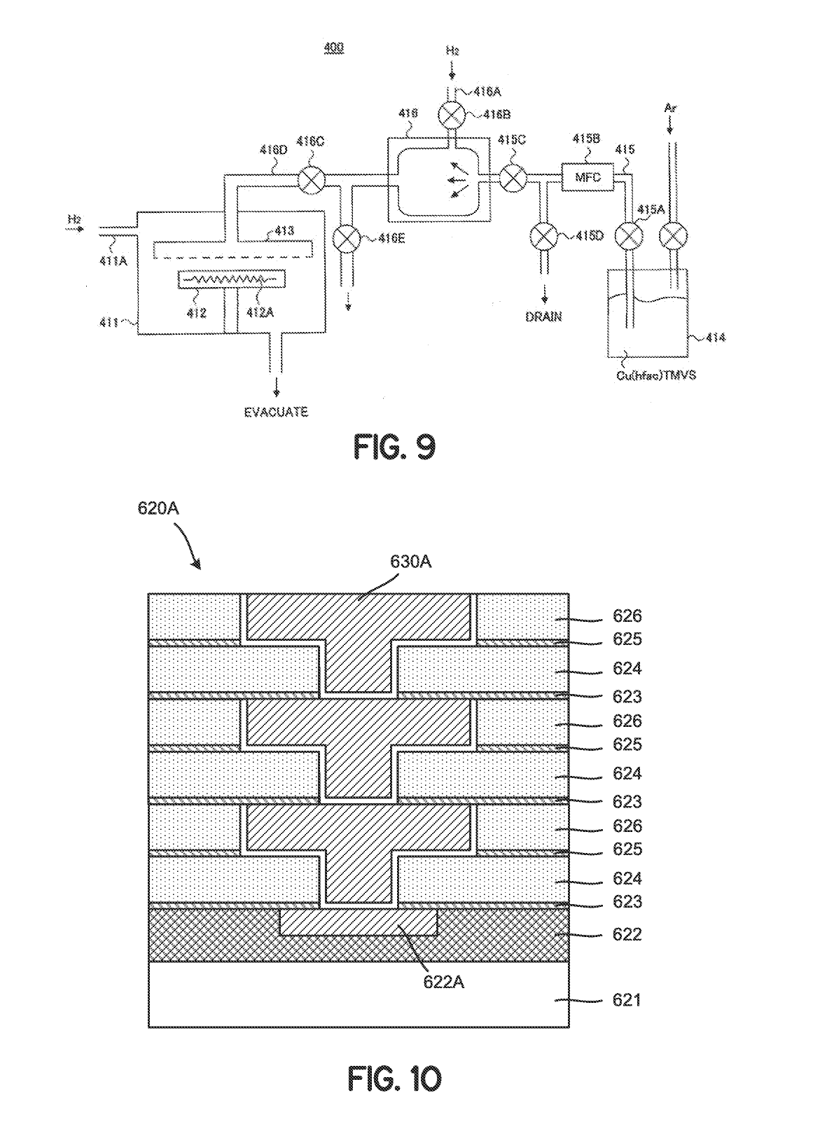

FIG. 9 is a schematic diagram of a CVD system used for depositing a Cu seed layer according to an embodiment of the invention. The CVD system 400 includes a process chamber 411 containing a substrate holder 412 with heater 412A. The process chamber 411 may be evacuated by a dry pump (not shown). The process chamber contains a showerhead 413 that faces a substrate (not shown) on the substrate holder 412, where the showerhead 413 supplies a gaseous Cu precursor compound to the surface of the substrate on the substrate holder 412. H₂ gas is supplied to the process chamber 411 from gas line 411A prior to depositing the Cu seed layer, in order to stabilize the gas pressure in the process chamber 411.

The Cu precursor compound is contained in source container 414 as a liquid, and Ar gas supplied to the source container 414 to flow the liquid precursor compound through precursor supply line 415 and valve 415A. The precursor supply line 415 and valve 415A are maintained at a predetermined temperature.

The liquid precursor compound is flowed through a mass flow controller 415B and a valve 415C controlled by the mass flow controller 415B, to a vaporizer 416. In one example, Cu(hexafluoroacetylacetonato) trimethylvinylsilane [(Cu(hfac)TMVS)] may be used as the precursor compound, and the vaporizer 416 maintained at a temperature of between 50° C. and 70° C. In addition, the precursor supply line 415 contains a drain valve 415D.

In the vaporizer 416, the precursor compound is vaporized to form a vapor or gas that is supplied to the showerhead 413 in the process chamber 411 using valve 416C. The vaporized precursor compound is supplied together with a H₂ gas from the line 416A using the valve 416B, where the line 416A and the valve 416B are maintained between of room temperature and about 60° C. The source supply line 416D, including the valve 416C, and a line extending from the vaporizer 416 to the process chamber 411 may be maintained at the same or similar temperature as the vaporizer to avoid condensation of the vaporized precursor compound. Furthermore, the showerhead 413 and the process chamber 411 may be maintained at a temperature between 50° C. and 70° C. The vaporizer 416 may be evacuated using a dry pump (not shown) and a valve 416E.

The CVD system 400 depicted in FIG. 9 is used to deposit the Cu seed layer 629 of FIG. 6F in the process chamber 411. Alternately, the Cu seed layer 629 may be deposited by a PVD process.

After forming the Cu seed layer 629 in FIG. 6F, the substrate is moved to a plating system to form bulk Cu film 630 of FIG. 6G on the Cu seed layer 629 by an electrolytic or non-electrolytic plating process.

After a thermal annealing step, the bulk Cu film 630 and the barrier metal film 628 on the dielectric film 626 are removed by a CMP process to form the structure 620 shown in FIG. 6H, where the trench 626A and the via 624A are filled with Cu metal.

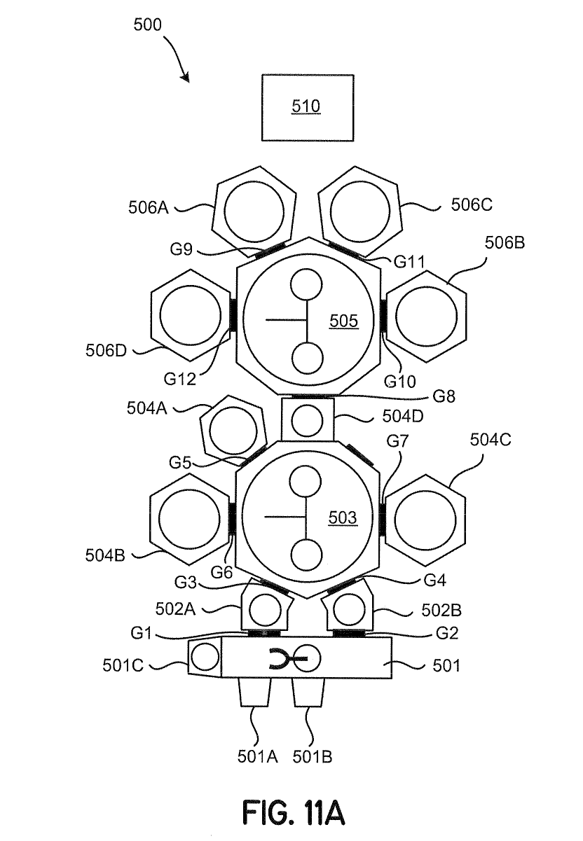

FIG. 10 is a schematic diagram showing a multilayer interconnect structure according to an embodiment of the invention. As those skilled in the art will readily recognize, the multilayer interconnect structure 620A may be formed by repeating formation of the structure shown in FIG. 6H.

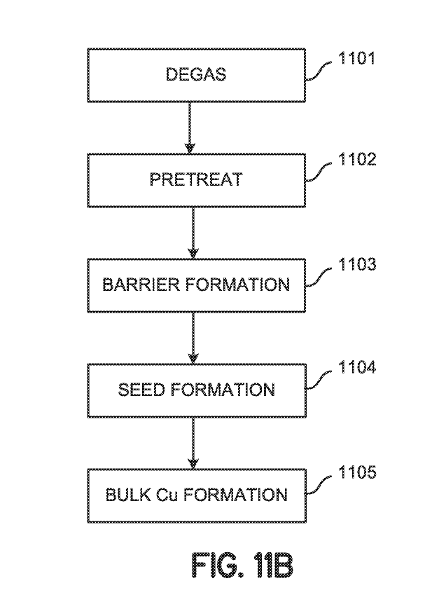

FIG. 11A is a schematic diagram of a substrate processing tool according to an embodiment of the invention. FIG. 11B is a process flow diagram for integrated substrate processing using the substrate processing tool depicted in FIG. 11A.

Referring to FIG. 11A, the substrate processing tool 500 contains a wafer (substrate) transfer system 501 that includes cassette modules 501A and 501B, and a wafer alignment module 501C. Load-lock chambers 502A and 502B are coupled to the wafer transfer system 501 using gate valves G1 and G2, respectively. The wafer transfer system 501 is maintained at atmospheric pressure but a clean environment is provided by purging with an inert gas.

The load-lock chambers 502A and 502B are coupled to a vacuum wafer transfer system 503 using gate valves G3 and G4. The vacuum wafer transfer system 503 includes a wafer transfer robot and is coupled to degassing system 504A, (pretreating) processing system 504B described in FIG. 4 for pretreating a substrate, and PEALD barrier metal system 504C. The system 504C may be the PEALD system 300 of FIG. 7. The systems 504A, 504B, and 504C are coupled to the vacuum wafer transfer system 503 using gate valves G5, G6, and G7, respectively.

Furthermore, the vacuum wafer transfer system 503 is coupled to a second vacuum wafer transfer system 505 through wafer handling system 504D and gate valve G8. The second vacuum wafer transfer system 505 includes a second wafer transfer robot. Coupled to the second vacuum wafer transfer system 505 is Cu IPVD or Cu CVD system 506A configured for forming the Cu seed layer 629 of FIG. 6G. One example of an IPVD system is described in U.S. Pat. No. 6,287,435. One example of a Cu CVD system 400 is depicted in FIG. 9.

A Ru CVD or Ru IPVD system 506D for depositing a Ru film as a part of the barrier metal film 628 is coupled to the second vacuum wafer transfer system 505. One example of a Ru CVD system 506D is described U.S. patent application Publication Ser. No. 10/996,145, entitled METHOD AND DEPOSITION SYSTEM FOR INCREASING DEPOSITION RATES OF METAL LAYERS FROM METAL-CARBONYL PRECURSORS, the entire content of which is herein incorporated by reference. In addition, an IPVD barrier metal system 506C is coupled to the second vacuum wafer transfer system 505. The IPVD barrier metal system 506C is an alternate system to the PEALD barrier metal system 504C for depositing a Ta-containing, Ti-containing, or W-containing barrier metal film 628 of FIG. 6E. In addition, an Ar sputtering system 506B is coupled to the second vacuum wafer transfer system 505. The Ar sputtering system 506B may, for example, be utilized to substantially completely remove the barrier metal film 628 from the bottom of the via 624A and at least partially from the bottom of the trench 626A prior to the forming Cu seed layer 629. The systems 506A, 506B, 506C, and 506D are coupled to the second vacuum wafer transfer system 505 using gate valves G9, G10, G11, and G12, respectively.

The substrate processing tool 500 includes a controller 510 that can be coupled to and control any or all of the processing systems and processing elements depicted in FIG. 11A during the integrated substrate processing. Alternatively, or in addition, controller 510 can be coupled to one or more additional controllers/computers (not shown), and controller 510 can obtain setup and/or configuration information from an additional controller/computer. The controller 510 can be used to configure any or all of the processing systems and processing elements, and the controller 510 can collect, provide, process, store, and display data from any or all of the processing systems and processing elements. The controller 510 can comprise a number of applications for controlling any or all of the processing systems and processing elements. For example, controller 510 can include a graphic user interface (GUI) component (not shown) that can provide easy to use interfaces that enable a user to monitor and/or control one or more processing systems processing elements.

The controller 510 can include a microprocessor, memory, and a digital I/O port capable of generating control voltages sufficient to communicate, activate inputs, and exchange information with the substrate processing tool 500 as well as monitor outputs from the substrate processing tool 500. For example, a program stored in the memory may be utilized to activate the inputs of the substrate processing tool 500 according to a process recipe in order to perform integrated substrate processing. One example of the controller 510 is a DELL PRECISION WORKSTATION 610™, available from Dell Corporation, Austin, Tex.

However, the controller 510 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 510 may be locally located relative to the substrate processing tool 500, or it may be remotely located relative to the substrate processing tool 500. For example, the controller 510 may exchange data with the substrate processing tool 500 using at least one of a direct connection, an intranet, the Internet and a wireless connection. The controller 510 may be coupled to an intranet at, for example, a customer site (i.e., a device maker, etc.), or it may be coupled to an intranet at, for example, a vendor site (i.e., an equipment manufacturer). Additionally, for example, the controller 510 may be coupled to the Internet. Furthermore, another computer (i.e., controller, server, etc.) may access, for example, the controller 510 to exchange data via at least one of a direct connection, an intranet, and the Internet. As also would be appreciated by those skilled in the art, the controller 510 may exchange data with the substrate processing tool 500 via a wireless connection.

As those skilled in the art will readily recognize, embodiments of the invention may not require the use of all the processing systems depicted in FIG. 11A. For example, PEALD barrier metal system 504C and IPVD barrier metal system 506C may be alternate systems for depositing the Ta-containing part of the barrier metal film 628 of FIG. 6E. Thus, some embodiments of the invention may include the use of less than all the processing systems depicted in FIG. 11A.

Referring now to FIGS. 11A and 11B, a wafer containing the structure 620 depicted in FIG. 6D is provided in the cassette modules 501A or 501B for processing in the substrate processing tool 500. The wafer is introduced into the vacuum wafer transfer system 503 from the wafer transfer system 501 through the gate valve G1 and the load-lock chamber 502A or through the gate valve G2 and the load-lock chamber 502B, after a wafer aligning step in the wafer alignment module 501C. The wafer is then transferred from the vacuum wafer transfer system 503 to the degassing system 504A through the gate valve G5. In the degassing system 504A, the wafer may be heated and/or exposed to ultraviolet irradiation in an inert gas environment in step 1101 to remove water and any residual gas from the wafer.

After the degassing step 1101 in the degassing system 504A, the wafer is returned to the vacuum wafer transfer system 503 through the gate valve G5, and next the wafer is transported to the (pretreating) processing system 504B through the gate valve G6. In step 1102, the wafer is pretreated by exposure to hydrogen radicals in the pretreating processing system 504B as shown in FIG. 6D.

Following the pretreating step 1102, the wafer is returned to the vacuum wafer transfer system 503 through the gate valve G6.

Next, a barrier metal film 628 depicted in FIG. 6E is deposited onto the pretreated wafer in step 1103. According to one embodiment of the invention, the barrier metal film 628 depicted in FIG. 6F may contain alternating Ta-containing films, including TaN films or TaCN films and Ta films. For example, the Ta-containing films can include TaN(TaCN)/Ta or Ta/TaN(TaCN). According to another embodiment of the invention, the barrier metal film 628 may further contain a Ru film on the alternating TaN (TaCN) and Ta films, for example, TaN (TaCN)/Ta/Ru. According to still another embodiment of the invention, the barrier metal film 628 may contain a Ru film on a TaN (TaCN) film.

According to one embodiment of the invention, in step 1103, the wafer may be transferred to the PEALD barrier metal deposition system 504C for depositing a Ta-containing barrier metal film 628 by a PEALD process. Following formation of the barrier metal film 628 in the PEALD barrier metal deposition system 504C, the wafer is returned to the vacuum wafer transfer system 503 through the gate valve G7, and then transferred to the second vacuum wafer transfer system 505 from the wafer handling system 504D through the gate valve G8. Once in the second vacuum wafer transfer system 505, the wafer may then be introduced into the Cu CVD or Cu IPVD system 506A through the gate valve G9 for depositing, in step 1104, the Cu seed layer 629 depicted in FIG. 6G.

After formation of the Cu seed layer 629 in step 1104, the wafer is returned to the second vacuum wafer transfer system 505 through the gate valve G9 and then the wafer is transferred to the vacuum wafer transfer system 503 through the gate valve G8 and the wafer handling system 504D. Next, the wafer is returned to the wafer transfer system 501 from the vacuum wafer transfer system 503 through the gate valve G3, load-lock chamber 502A and the gate valve G1, or through the gate valve G4, the load-lock chamber 502B and the gate valve G2. Thereafter, the wafer is returned to the cassette module 501A or 501B. Once removed from the substrate processing tool 500, in step 1105, the bulk Cu film 630 depicted in FIG. 6G is plated on the Cu seed layer 629 in a Cu plating system (not shown).

According to another embodiment of the invention, in step 1103, the wafer may be transferred to the second vacuum wafer transfer system 505 and to the IPVD barrier metal system 506C for depositing a Ta-containing barrier metal film 628 by an IPVD process. Thereafter, in step 1104, a Cu seed layer 629 may be deposited onto the barrier metal film 628 and a bulk Cu film 630 plated onto the Cu seed layer 629 as described above.

According to still another embodiment of the invention, step 1103 may further include depositing a Ru film onto a Ta-containing film to form the barrier metal film 628. The Ru film may be deposited in the processing system 506D by Ru CVD or Ru IPVD. Thereafter, in step 1104, a Cu seed layer 629 may be deposited onto the barrier metal film 628 and a bulk Cu film 630 plated onto the Cu seed layer 629 as described above.

According to one embodiment of the invention, step 1104 may be omitted and a Ru film deposited in step 1103 onto a Ta-containing film may act as a barrier and a seed layer for subsequent Cu plating in step 1105.

According to one embodiment of the invention, the barrier metal film 628 may be substantially completely removed from the bottom of the via 624A and at least partially from the bottom of the trench 626A by sputter etching in processing system 506B prior to depositing a Cu seed layer 629.

Although only certain embodiments of this invention have been described in detail above, those skilled in the art will readily appreciate that many modifications are possible in the exemplary embodiment without materially departing from the novel teachings and advantages of this invention. Accordingly, all such modifications are intended to be included within the scope of this invention.

What is claimed is:

1. A method of integrated substrate processing in a substrate processing tool, comprising:
providing a substrate containing an etch feature in a dielectric film, wherein a metal interconnect pattern formed underneath the etch feature is exposed; and
performing an integrated process on the substrate in the substrate processing tool, the process comprising:
pretreating exposed surfaces of the etch feature and the exposed metal interconnect pattern with a flow of hydrogen radicals generated by thermal decomposition of H₂ gas by a hot filament hydrogen radical source separated from the substrate by a showerhead plate containing gas passages facing the substrate;
depositing a barrier metal film over the pretreated exposed surfaces; and
forming a Cu metal film on the barrier metal film.

2. The method of claim 1, wherein the etch feature comprises a trench, a via, or a combination thereof.

3. The method of claim 1, wherein the pretreating terminates the exposed surfaces of the dielectric film with hydrogen.

4. The method of claim 1, wherein the pretreating reduces a metal oxide layer of the exposed metal interconnect pattern to the corresponding metal.

5. The method of claim 4, wherein the exposed metal interconnect pattern comprises Cu.

6. The method of claim 1, wherein the H₂ gas is mixed with an inert gas.

7. The method of claim 1, wherein the depositing a barrier metal film comprises
depositing a Ta-containing film over the pretreated exposed surfaces.

8. The method of claim 7, wherein the depositing a Ta-containing film comprises
depositing a TaN or TaCN film.

9. The method of claim 7, wherein the depositing a Ta-containing film comprises
depositing a TaN or TaCN film, and
depositing a Ta film over the TaN or TaCN film.

10. The method of claim 7, wherein the depositing a barrier metal film further comprises
depositing a Ru film over the Ta-containing film.

11. The method of claim 1, wherein the forming a Cu metal film comprises
depositing a Cu seed layer over the barrier metal film, and
plating a bulk Cu film onto the Cu seed layer.

12. The method of claim 10, wherein the forming a Cu metal film comprises
plating bulk Cu onto the Ru film.

13. The method of claim 1, wherein the pretreating comprises
maintaining a temperature of a metal wire filament in the hot filament hydrogen radical source at a temperature between 1200° C. and 2500° C.

14. The method of claim 1, wherein the pretreating comprises
maintaining a temperature of a metal wire filament in the hot filament hydrogen radical source at a temperature between 1400° C. and 1600° C.

15. The method of claim 1, wherein the pretreating comprises
maintaining the substrate at a temperature between room temperature and 500° C.

16. The method of claim 1, wherein the etch feature comprises a trench and a via, each having a sidewall and a bottom, the method further comprising
removing the barrier metal film substantially completely from the bottom of the via and at least partially from the bottom of the trench by sputter etching prior to the forming a Cu metal film.

17. The method of claim 1, wherein the depositing a barrier metal film comprises
depositing a W-containing film or a Ti-containing film over the pretreated exposed surfaces.

18. The method of claim 1, wherein the hydrogen radicals substantially comprise neutral hydrogen radicals.

19. The method of claim 1, wherein the pretreating, depositing, and any intervening steps are performed without exposing the substrate to air.

20. A method of integrated substrate processing in a substrate processing tool, comprising:
providing a substrate containing an etch feature in a dielectric film, the etch feature comprising a trench having a sidewall and a bottom, a via at the bottom of the trench, the via having a sidewall and a bottom, and a Cu interconnect pattern exposed at the bottom of the via; and
performing an integrated process on the substrate in the substrate processing tool, the process comprising:
pretreating exposed sidewall and bottom surfaces of the etch feature and the exposed Cu interconnect pattern with a flow of hydrogen radicals generated by thermal decomposition of H₂ gas by a hot filament hydrogen radical source separated from the substrate by a showerhead plate containing gas passages facing the substrate;
depositing a barrier metal film over the pretreated exposed sidewall and bottom surfaces, wherein the pretreating, depositing, and any intervening steps are performed without exposing the substrate to air, and the barrier metal film comprises a Ta-containing film and a Ru metal film over the Ta-containing film; and
forming a Cu metal film on the barrier metal film by depositing a Cu seed layer over the Ru metal film and plating a bulk Cu film onto the Cu seed layer.

21. The method of claim 20, further comprising
removing the barrier metal film substantially completely from the bottom of the via and at least partially from the bottom of the trench by sputter etching prior to the forming a Cu metal film.
